(19) United States
(12) Patent Application Publication
(10) Pub. No.: US 2020/0400749 A1
(43) Pub. Date: Dec. 24, 2020

(54) CURRENT MEASURING DEVICE, ENERGY STORAGE APPARATUS, AND CURRENT MEASUREMENT METHOD

(71) Applicant: GS Yuasa International Ltd., Kyoto-shi (JP)

(72) Inventor: Yuki IMANAKA, Kyoto-shi, Kyoto (JP)

(21) Appl. No.: 16/977,768

(22) PCT Filed: Mar. 7, 2019
(86) PCT No.: PCT/JP2019/009075

§ 371 Date: Sep. 2, 2020

(30) Foreign Application Priority Data
Mar. 9, 2018 (JP) 2018-042795

(51) Int. Cl. G01R 31/385; G01R 31/327; B60L 58/10; H02J 7/00

(52) U.S. Cl. CPC G01R 31/385; G01R 31/3275; H02J 7/00302; H02J 7/00306; B60L 58/10

(57) ABSTRACT

A current measuring device of an energy storage device includes: a current breaker that is provided on a current path of the energy storage device; a first current sensor that is on the current path and measures a current of the energy storage device; a second current sensor that is connected in parallel with the current breaker; and a processing unit, in which the second current sensor includes a sensor having a smaller resolution than the first current sensor, and the processing unit performs measurement processing of measuring the current of the energy storage device by selectively using the first current sensor and the second current sensor according to a predetermined selection condition, and failure detection processing of detecting a failure in the current breaker on the basis of a measured value of the second current sensor when the current breaker is switched to open or close.

### TECHNICAL FIELD

The present invention relates to a technology for measuring a current of an energy storage device.

### BACKGROUND ART

A battery measures a current with a current sensor or the like in order to monitor the state of an energy storage device. In Patent Document 1 below, a motor driving battery mounted on an electric vehicle is connected to a load circuit including a drive motor through a main relay. A precharge circuit is provided in parallel with the main relay and a load current flowing through the load circuit is detected by a first current detection circuit. A second current detection circuit that detects the load current by detecting the voltage at both ends of a precharge resistor is provided. The two current detection circuits are used by switching the main relay according to the size of the load current.

### PRIOR ART DOCUMENT

### Patent Document

Patent Document 1: JP-A-2002-267698

### SUMMARY OF THE INVENTION

### Problems to be Solved by the Invention

When a current breaker such as a main relay fails, the current cannot be interrupted at the time of overdischarge or overcharge. It has been required to use a current sensor to diagnose a failure of the current breaker so that the current can be interrupted when an energy storage device is over-discharged or over-charged.

The present invention has been completed on the basis of the above circumstances, and aims to maintain current measurement accuracy by selectively using two current sensors having different resolutions, and diagnose a failure of a current breaker.

### Means for Solving the Problems

A current measuring device of an energy storage device according to an aspect of the present invention includes: a current breaker that is provided on a current path of the energy storage device; a first current sensor that is on the current path and measures a current of the energy storage device; a second current sensor that is connected in parallel with the current breaker; and a processing unit. The second current sensor is a sensor having a smaller resolution than the first current sensor, and the processing unit performs measurement processing of measuring the current of the energy storage device by selectively using the first current sensor and the second current sensor according to a predetermined selection condition, and failure diagnosis processing of diagnosing whether or not there is a failure in the current breaker on the basis of a measured value of the second current sensor when the current breaker is switched to open or close. Resolution is the smallest unit of current that can be identified by a sensor.

The present technology can be applied to an energy storage apparatus including an energy storage device and a current measuring device, and a current measurement method.

### Advantages of the Invention

By selectively using two current sensors having different resolutions, it is possible to maintain current measurement accuracy and diagnose a failure of a current breaker.

### BRIEF DESCRIPTION OF THE DRAWINGS

FIG. 1 is a side view of a vehicle.

FIG. 2 is an exploded perspective view of a battery.

FIG. 3(a) is a plan view of a secondary battery shown in FIG. 2, and FIG. 3(b) is a sectional view taken along line A-A of FIG. 3(a).

FIG. 4 is a perspective view showing a state where the secondary batteries are housed in a main body of FIG. 2.

FIG. 5 is a perspective view showing a state where bus bars are attached to the secondary batteries of FIG. 4.

FIG. 6 is a block diagram showing an electrical configuration of the battery.

FIG. 7 is a block diagram showing the electrical configuration of the battery.

FIG. 8 is a flowchart showing a flow of current measurement processing.

### MODE FOR CARRYING OUT THE INVENTION

A current measuring device of an energy storage device according to one embodiment includes: a current breaker that is provided on a current path of the energy storage device; a first current sensor that is on the current path and measures a current of the energy storage device; a second current sensor that is connected in parallel with the current breaker; and a processing unit. The second current sensor is a sensor having higher resolution than the first current sensor, and the processing unit performs measurement processing of measuring the current of the energy storage device by selectively using the first current sensor and the second current sensor according to a predetermined selection condition, and failure diagnosis processing of diagnosing whether or not there is a failure in the current breaker on the basis of a measured value of the second current sensor when the current breaker is switched to open or close.

By using the two current sensors having different resolutions according to the selection conditions, a wide range of currents can be measured accurately. By using the current measuring function of the current sensor, it is possible to diagnose whether or not there is a failure in the current breaker. Accordingly it is possible to curb continuous usage of a failed current breaker.

The energy storage device is preferably used to start an engine for driving a vehicle. When the engine is started, a large current flows through the energy storage device used for starting the engine. This tends to cause failure of the current breaker. By applying the present technology to an energy storage device used for starting an engine, it is possible to solve problems peculiar to the energy storage device used for starting an engine such as the tendency of the energy storage device to become overdischarged or overcharged due to a failure of a current breaker.

The processing unit preferably opens the current breaker and measures a current of the energy storage device using the second current sensor while the vehicle is parked. By using the second current sensor having higher resolution than the first current sensor in a parked state, it is possible to accurately detect the dark current of the vehicle.

The processing unit preferably closes the current breaker and measures a current of the energy storage device using the first current sensor when the engine is started. By using the first current sensor when the engine is started, it is possible to accurately detect a large current discharged from the battery when the engine is started.

In the failure diagnosis processing, the processing unit preferably diagnoses whether or not there is a failure in the current breaker on the basis of whether or not a measured value of the first current sensor and a measured value of the second current sensor match. Whether or not there is a failure in the current breaker can be diagnosed on the basis of whether or not the measured values of the two current sensors match.

A current measurement method for measuring a current of an energy storage device using a first current sensor that is arranged on a current path of the energy storage device, and a second current sensor that is connected in parallel with a current breaker arranged on the current path of the energy storage device and has a smaller resolution than the first current sensor, the method including the steps of performing failure diagnosis processing of diagnosing whether or not there is a failure in the current breaker on the basis of a measured value of the second current sensor when the current breaker is switched to open or close, and when it is determined that there is no failure in the failure diagnosis processing, performing measurement processing of measuring the current of the energy storage device by selectively using the first current sensor and the second current sensor according to a predetermined selection condition. With this method, it is possible to curb measurement of a current while the two current sensors cannot be switched due to a failure of the current breaker.

### Embodiment 1

1. Structure Description of Battery BT

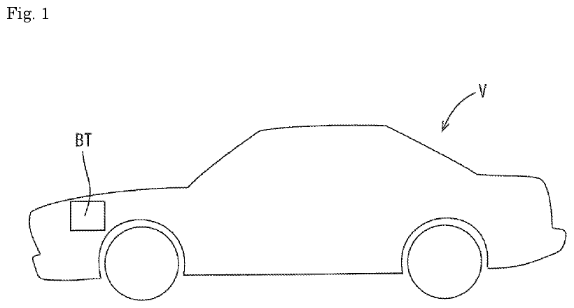

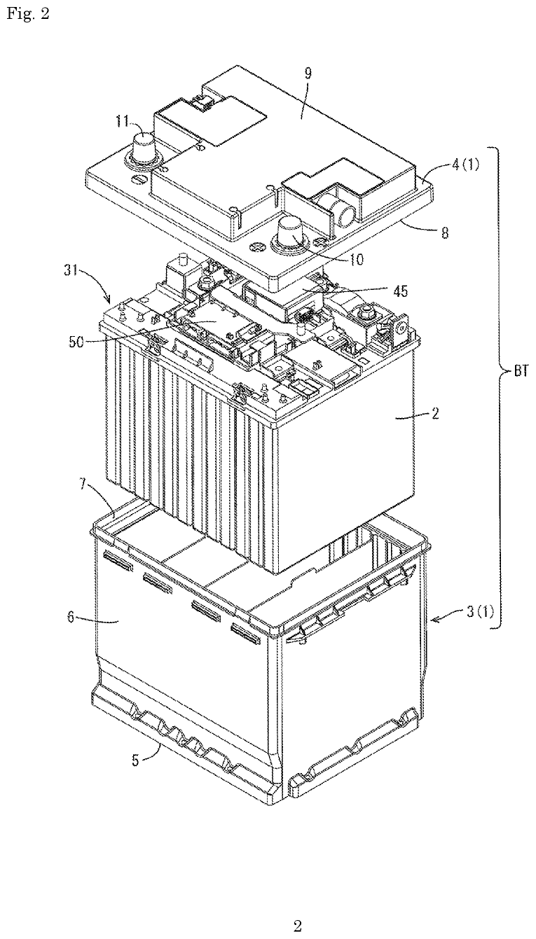

FIG. 1 is a side view of a vehicle V and FIG. 2 is an exploded perspective view of a battery BT. The vehicle V is an engine-driven vehicle. The vehicle V includes the battery BT that is an energy storage apparatus. As shown in FIG. 2, the battery BT includes a housing 1, an assembled battery 40 housed inside the housing 1, and a circuit board unit 31. The battery BT is used to start an engine 100 mounted on the vehicle V.

The housing 1 is configured of a main body 3 and lid 4 made of a synthetic resin material. The main body 3 has a bottomed tubular shape, and is configured of a bottom surface portion 5 that is rectangular in plan view and four side surface portions 6 that stand up from four sides of the bottom surface portion 5 to form a tubular shape. An upper opening 7 is formed in an upper end portion by the four side surface portions 6.

The lid 4 has a rectangular shape in plan view, and a frame 8 extends downward from four sides of the lid 4. The lid 4 closes the upper opening 7 of the main body 3. A protruding portion 9 having a substantially T-shape in plan view is formed on an upper surface of the lid 4. On the upper surface of the lid 4, of two parts where the protruding portion 9 is not formed, a positive external terminal 10 is fixed to one corner and a negative external terminal 11 is fixed to the other corner.

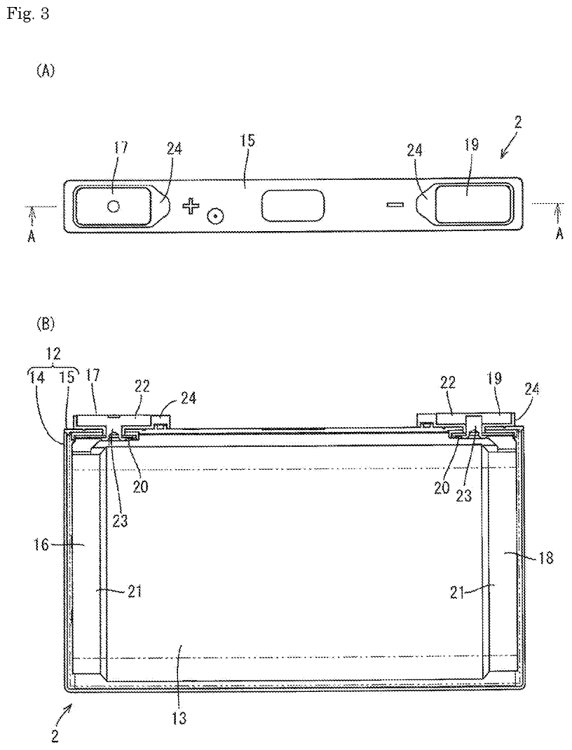

As shown in FIGS. 3(a) and 3(b), a secondary battery 2 has an electrode assembly 13 housed together with a nonaqueous electrolyte in a rectangular parallelepiped case 12. The case 12 is configured of a case body 14 and a cover 15 that closes an upper opening of the case body 14.

Although not shown in detail, the electrode assembly 13 has a separator made of a porous resin film between a negative electrode element in which a substrate made of copper foil is coated with an active material and a positive electrode element in which a substrate made of aluminum foil is coated with an active material. The parts are all strip-shaped, and are wound in a flat shape so that they can be accommodated in the case body 14 in a state where the negative electrode element and the positive electrode element are shifted to opposite sides in the width direction from the separator.

A positive electrode terminal 17 is connected to the positive electrode element through a positive electrode current collector 16, and a negative electrode terminal 19 is connected to the negative electrode element through a negative electrode current collector 18. Each of the positive electrode current collector 16 and the negative electrode current collector 18 includes a seat portion 20 having a flat plate shape and a leg portion 21 extending from the seat portion 20. A through hole is formed in the seat portion 20. The leg portion 21 is connected to the positive electrode element or the negative electrode element. The positive electrode terminal 17 and the negative electrode terminal 19 each includes a terminal body portion 22 and a shaft portion 23 protruding downward from a center portion of a lower surface of the terminal body portion 22. Among the parts, the terminal body portion 22 and the shaft portion 23 of the positive electrode terminal 17 are integrally formed of aluminum (single material). In the negative electrode terminal 19, the terminal body portion 22 is made of aluminum and the shaft portion 23 is made of copper, and these are assembled. The terminal body portions 22 of the positive electrode terminal 17 and the negative electrode terminal 19 are arranged in both end portions of the cover 15 with gaskets 24 made of an insulating material interposed therebetween, and are exposed outward of the gaskets 24.

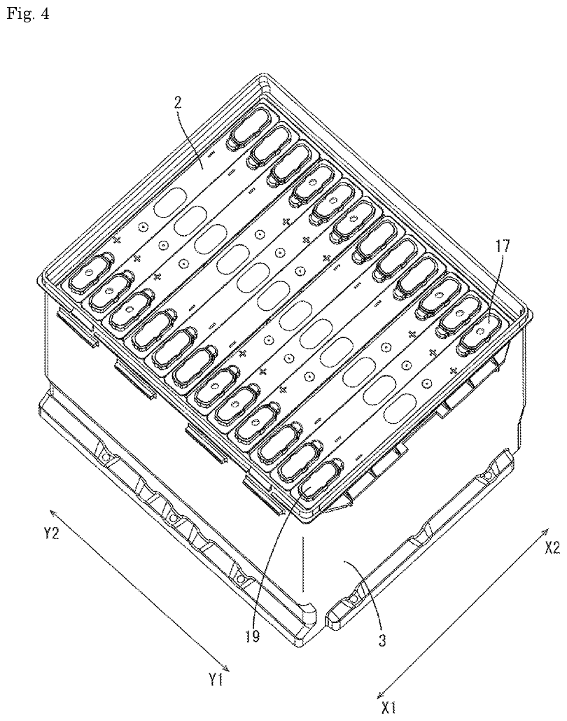

As shown in FIG. 4, the secondary battery 2 having the above-described configuration is housed in the main body 3 in a state where multiple (for example, twelve) secondary batteries 2 are arranged side by side in the width direction. Three secondary batteries 2 from one end side toward the other end side of the main body 3 (direction of arrow Y1 to Y2) form one set. The secondary batteries 2 are arranged such that adjacent secondary batteries 2 of the same set have the same terminal polarities, while adjacent secondary batteries 2 of adjacent sets have opposite terminal polarities. In the three secondary batteries 2 (first set) located closest to the arrow Y1 side, the arrow X1 side is the negative electrode and the arrow X2 side is the positive electrode. In the three secondary batteries 2 (second set) adjacent to the first set, the arrow X1 side is the positive electrode and the arrow X2 side is the negative electrode. A third set adjacent to the second set has the same arrangement as the first set, and a fourth set adjacent to the third set has the same arrangement as the second set.

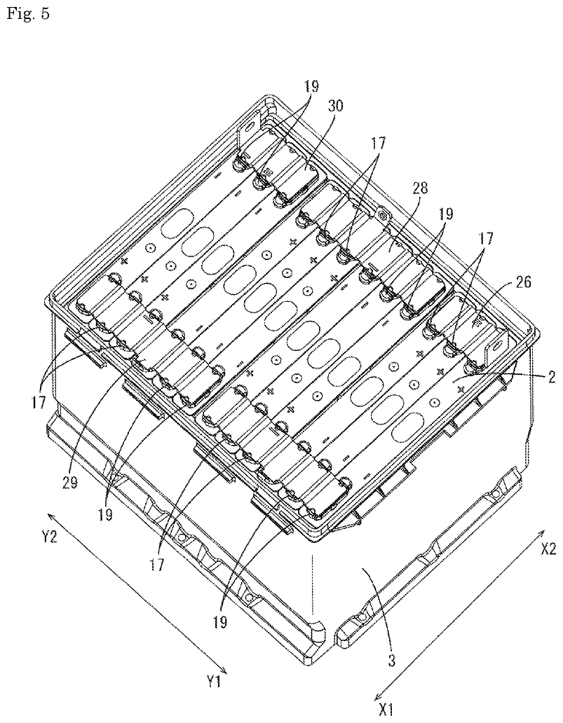

As shown in FIG. 5, terminal bus bars 26 to 30 as conductive members are connected to the positive electrode terminals 17 and the negative electrode terminals 19 by welding. On the arrow X2 side of the first set, a group of positive electrode terminals 17 is connected by the first bus bar 26. Between the first set and the second set, a group of negative electrode terminals 19 of the first set and a group of positive electrode terminals 17 of the second set are connected by the second bus bar 27 on the arrow X1 side. Between the second set and the third set, a group of negative electrode terminals 19 of the second set and a group of positive electrode terminals 17 of the third set are connected by the third bus bar 28 on the arrow X2 side. Between the third set and the fourth set, a group of negative electrode terminals 19 of the third set and a group of positive electrode terminals 17 of the fourth set are connected by the fourth bus bar 29 on the arrow X1 side. On the arrow X2 side of the fourth set, a group of negative electrode terminals 19 is connected by the fifth bus bar 30.

The secondary batteries 2 are connected in parallel in the same set, and are connected in series between different sets. Accordingly, the twelve secondary batteries 2 are arranged so that four sets of three parallel-connected batteries are connected in series. The secondary battery 2 is a lithium ion secondary battery, for example.

The first bus bar 26 that connects the group of positive electrode terminals of the first set is connected to the positive external terminal 10, and the fifth bus bar 30 that connects the group of negative electrode terminals of the fourth set is connected to the negative external terminal 11.

2. Description of Electrical Configuration of Battery BT

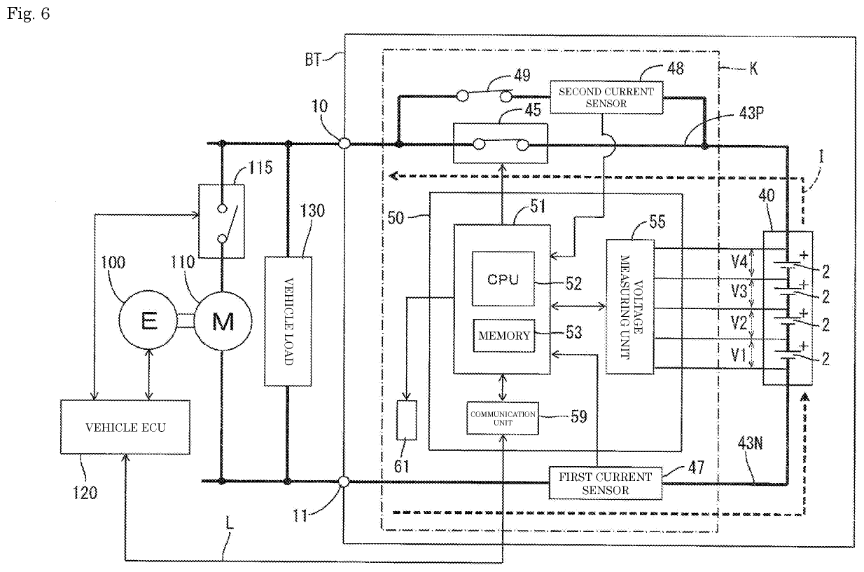

The electrical configuration of the battery BT will be described with reference to FIG. 6. The battery BT includes the assembled battery 40, a current breaker 45, a first current sensor 47, a second current sensor 48, a switch 49, a management device 50, and a warning lamp 61. Reference sign K indicated by a chain line frame in FIG. 6 is an example of a “current measuring device” of the present invention.

The assembled battery 40 is configured of four sets of secondary batteries 2 connected in series. The current breaker 45, the assembled battery 40, and the first current sensor 47 are connected in series through conduction paths 43P and 43N. The current breaker 45 is arranged on the positive electrode side and the first current sensor 47 is arranged on the negative electrode side. The current breaker 45 is connected to the positive external terminal 10 through the conduction path 43P, and the first current sensor 47 is connected to the negative external terminal 11 through the conduction path 43N. The conduction paths 43P and 43N are examples of a “current path” of the present invention.

The current breaker 45 is arranged on the circuit unit 31. The current breaker 45 is a semiconductor switch such as a relay or an FET (field effect transistor), and interrupts the current by opening the conduction path 43P of the assembled battery 40.

The second current sensor 48 and the switch 49 are connected in series. A series circuit including the second current sensor 48 and the switch 49 is connected in parallel to the current breaker 45. A resolution B2 of the second current sensor 48 is smaller than a resolution B1 of the first current sensor 47 (B2<B1). The second current sensor 48 is suitable for measuring a minute current, and the first current sensor 47 is suitable for measuring a large current. The resolutions B1 and B2 are the minimum units of a current I that can be identified by the current sensors 47 and 48.

The first current sensor 47 and the second current sensor 48 are each connected to the management device 50 through a signal line, and measured values Ia and Ib of the two current sensors 47 and 48 are input to the management device 50. The switch 49 is provided to open and interrupt the current, together with the current breaker 45, when there is an abnormality in the assembled battery 40. The first current sensor 47, the second current sensor 48, and the switch 49 are arranged on the circuit unit 31.

The management device 50 is arranged on the circuit unit 31. The management device 50 includes a processing unit 51, a voltage measuring unit 55, and a communication unit 59.

The voltage measuring unit 55 measures voltages V1 to V4 of the secondary batteries 2 and a total voltage Vs of the assembled battery 40. The voltage measuring unit 55 outputs the data of the measured voltages V1 to V4 and Vs to the processing unit 51.

Vs=V1+V2+V3+V4 (1)

The processing unit 51 includes a CPU (central processing unit) 52 and a non-volatile memory 53. The processing unit 51 monitors the state of the assembled battery 40. Specifically, the processing unit 51 monitors whether or not the total voltage Vs of the assembled battery 40 and the battery voltages V1 to V4 of the secondary batteries 31 are within the usable range. The processing unit 51 monitors whether or not the current I of the assembled battery 40 is within the limit value, on the basis of the measured values Ia or Ib measured by the first current sensor 47 or the second current sensor 48.

The processing unit 51 further performs processing of estimating the SOC of the battery BT. The SOC can be calculated by the integral value of the current I with respect to time as shown in the following equations (2) and (3). Note that the sign of the current is positive when charging and negative when discharging.

SOC=Cr/Co×100 (2)

Here, Co is the full charge capacity of the secondary battery, and Cr is the residual capacity of the secondary battery.

SOC=SOCo+100×∫Idt/Co (3)

SOCo is the initial value of SOC, and I is the current.

The memory 53 stores pieces of data for the processing unit 51 to monitor the state of the assembled battery 40, calculate the SOC, and perform current measurement processing described later.

As shown in FIG. 6, a starter motor 110 is connected to the external terminals 10 and 11 of the battery BT through an IG switch (ignition switch) 115. The starter motor 110 is a starting device for the engine 100 mounted on the vehicle V. When the IG switch 115 is turned on, a current flows from the battery BT to the starter motor 110, and the starter motor 110 rotates. As a result, a crankshaft rotates and the engine 100 starts.

A vehicle ECU (Electronic Control Unit) 120 is mounted on the vehicle V and monitors the operating state of the engine 100, the state of the IG switch 115, and the like.

The management device 50 is communicably connected to the vehicle ECU 120 through a communication line L. The management device 50 can receive information on the operating state of the engine 100 and the operating state of the IG switch 115 from the vehicle ECU 120 by communication through the communication line L.

Not only the starter motor 110 but also another vehicle load 130 is connected to the external terminals 10 and 11 of the battery BT. The vehicle load 130 is a load mounted on the vehicle 1 and includes electrical components such as headlamps. Additionally the vehicle load 130 also includes a backup memory for the vehicle ECU 120, a security device equipped on the vehicle V and the like. FIG. 1 shows only the vehicle 1 and the battery BT, and omits the engine 100, the vehicle ECU 120, and the vehicle load 130.

3. Failure Diagnosis of Current Breaker and Current Measurement Processing

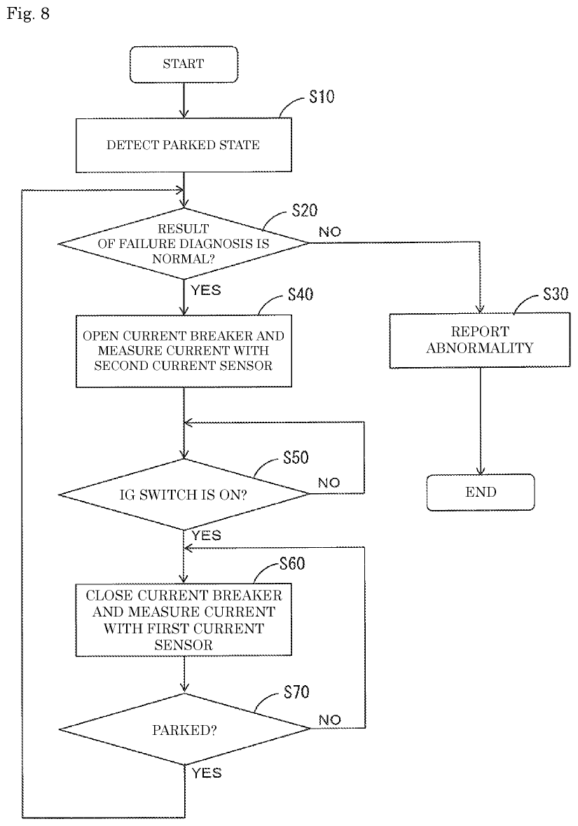

FIG. 8 is a flowchart showing the flow of current measurement processing of the assembled battery 40. In an initial state, both the current breaker 45 and the switch 49 are closed.

The processing unit 51 of the management device 50 first detects a parked state of the vehicle V (S10). A parked state is a state in which at least the engine 100 is stopped, and the vehicle does not move for a predetermined time.

A parked state can be determined by communication with the vehicle ECU 120. Since the vehicle ECU 120 stops communicating with the management device 50 in a parked state, it can be determined that the vehicle is parked when communication with the vehicle ECU 120 is stopped for a predetermined time or more.

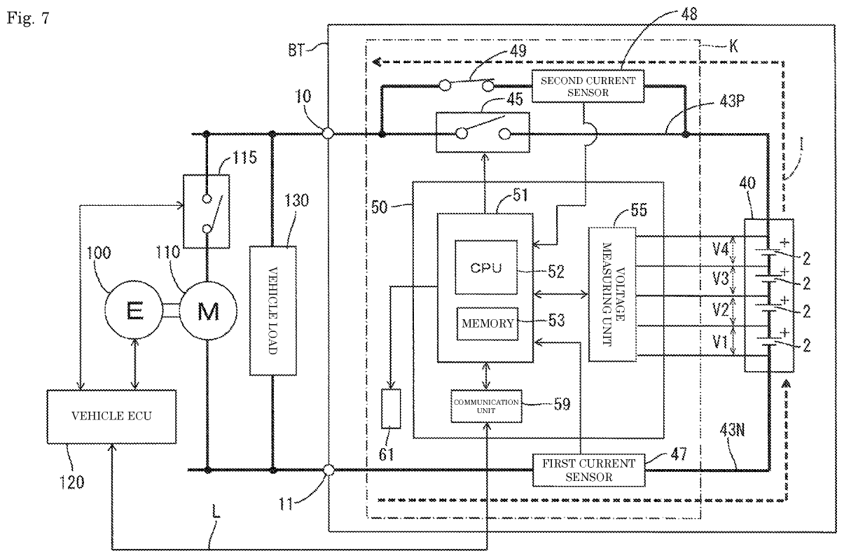

Upon detection of a parked state of the vehicle V, the processing unit 51 performs processing of diagnosing whether or not there is a failure in the current breaker 45 (S20). Failures include a close failure and an open failure. The close failure is a failure in which the current breaker 45 does not open even if an open command is given, and the current breaker 45 sticks in the closed state. The close failure can be determined from the measured values Ia and Ib of the first current sensor 47 and the second current sensor 48 when an open command is given to the current breaker 45. When the current breaker 45 operates normally (opens in response to open command), as shown in FIG. 7, the same amount of current flows through the first current sensor 47 and the second current sensor 48, and the measured value Ia of the first current sensor 47 and the measured value Ib of the second current sensor 48 become equal (Ia=Ib).

On the other hand, when the current breaker 45 has the close failure (does not open even when open command is given), the current I flows only to the current breaker 45 and does not flow to the second current sensor 48. Hence, the measured value Ia of the first current sensor 47 and the measured value Ib of the second current sensor 48 do not match (Ia≠Ib).

After giving an open command to the current breaker 45, if the measured value Ia of the first current sensor 47 and the measured value Ib of the second current sensor 48 match, the processing unit 51 determines that the current breaker 45 is “normal”. After giving an open command to the current breaker 45, if the measured value Ia of the first current sensor 47 and the measured value Ib of the second current sensor 48 do not match, the processing unit 51 determines that the current breaker 45 has the “close failure”.

The open failure is a failure in which the current breaker 45 does not close even if a close command is given, and the current breaker 45 sticks in the open state. The open failure can be determined from the measured values Ia and Ib of the first current sensor 47 and the second current sensor 48 when a close command is given to the current breaker 45. When the current breaker 45 operates normally (closes in response to close command), as shown in FIG. 6, the current I flows to the current breaker 45 and does not flow to the second current sensor 48. Hence, the measured value Ia of the first current sensor 47 and the measured value Ib of the second current sensor 48 do not match (Ia≠Ib).

On the other hand, when the current breaker 45 has the open failure (does not close even when close command is given), the same amount of current flows through both the first current sensor 47 and the second current sensor 48, and the measured value Ia of the first current sensor 47 and the measured value Ib of the second current sensor 48 become equal (Ia=Ib).

Hence, after giving a close command to the current breaker 45, if the measured value Ia of the first current sensor 47 and the measured value Ib of the second current sensor 48 do not match, the processing unit 51 determines that the current breaker 45 is “normal”. After giving a close command to the current breaker 45, if the measured value Ia of the first current sensor 47 and the measured value Ib of the second current sensor 48 match, the processing unit 51 determines that the current breaker 45 has the “open failure”.

The processing unit 51 sequentially performs diagnoses for the close failures and the open failures, and if the current breaker 45 has the close failure or the open failure, reports the abnormality to the outside. For example, the processing unit 51 lights the warning lamp 61 or notifies the vehicle ECU 120 of the failure of the current breaker 45 (S30).

When the current breaker 45 is normal (when there is neither close failure nor open failure), the management device 50 gives an open command to the current breaker 45 to open the current breaker 45 (S40). By opening the current breaker 45, as shown in FIG. 7, the second current sensor 48 and the switch 49 serve as a current-carrying path. Hence, the dark current of the vehicle V can be measured by the second current sensor 48.

The dark current of the vehicle V is a current consumed by the vehicle V (current discharged by battery BT) in a parked state, and is a minute current of 100 mA or less.

The dark current is a current consumed by a backup memory of the vehicle ECU 120, a security device equipped on the vehicle V, and the like. The second current sensor 48 has a smaller resolution and higher accuracy than the first current sensor 47, and therefore can accurately measure the dark current of the vehicle V. The dark current measurement by the second current sensor 48 is continued until it is detected that the IG switch 115 is turned on. High accuracy means that the error is small. As an example, the resolution B2 of the second current sensor 48 is preferably 0.1 mA or less.

After performing S40, the processing unit 51 performs processing of determining whether it is detected that the IG switch 115 is turned on (S50). When the IG switch 115 is switched from off to on by a user operation, the vehicle ECU 120 restarts communication and transmits information indicating that the IG switch 115 is switched to ON to the management device 50.

By receiving the information that the IG switch 115 is turned on from the vehicle ECU 120, the processing unit 51 can detect that the IG switch 115 is switched from off to on.

Upon detection of the ON state of the IG switch 115, the processing unit 51 gives a close command to the current breaker 45, closes the current breaker 45, and measures the current using the first current sensor 47 (S60).

When the IG switch 115 is switched to ON, as shown in FIG. 6, a cranking current flows from the battery BT to the starter motor 110 through the current breaker 45. As a result, the starter motor 110 is driven, the crankshaft is rotated, and the engine 100 is started.

Since the cranking current is a large current of about 1000 A, even the first current sensor 47 having a low resolution can relatively accurately measure the cranking current.

The measurement of the current by the first current sensor 47 is continued until a parked state of the vehicle V is detected. Accordingly after the engine is started, the current is measured using the first current sensor 47 while the vehicle V is running and while the vehicle V is stopped. Since a relatively large current of approximately several amperes or more flows between the vehicle V and the battery BT while the vehicle V is running or stopped, even the first current sensor 47 having a low resolution can measure the current accurately. As an example, the resolution B1 of the first current sensor 47 is preferably about 10 mA.

Alongside the current measurement by the first current sensor 47, the processing unit 51 determines whether the vehicle V is parked (S70). If the processing unit 51 determines that the vehicle V is parked, the processing proceeds to the second cycle, and the processing of S20 to S70 is performed.

4. Effect

By using the two current sensors 47 and 48 having different resolutions according to the state of the vehicle V, a wide range of currents can be measured accurately Additionally by using the current measuring function of the current sensors 47 and 48, it is possible to diagnose whether or not there is a failure in the current breaker 45. Accordingly, it is possible to curb continuous usage of a failed current breaker 45.

The battery BT is used for starting the engine 100, and a large cranking current flows when the engine is started. This tends to cause failure of the current breaker 45. By applying the present technology to the battery BT used for starting an engine, it is possible to solve problems peculiar to the battery BT used for starting an engine such as the tendency of the assembled battery 40 to become overdischarged or overcharged due to a failure of the current breaker 45.

While in a parked state when a minute dark current flows, the second current sensor 48 having a small resolution is used to measure the current I of the battery BT, whereas at the engine start when a large current flows, the first current sensor 47 is used to measure the current I of the battery BT. For this reason, a wide range of currents I from the dark current in a parked state to the cranking current at the engine start can be detected with high accuracy and the accuracy of estimating the SOC of the battery BT can be increased.

### Other Embodiments

The present invention is not limited to the embodiment described with reference to the above description and drawings, and the following embodiments, for example, are also included in the technical scope of the present invention.

(1) In the above embodiment, the secondary battery 2 is exemplified as an example of the energy storage device. The energy storage device is not limited to the secondary battery 2, and may be a capacitor or the like. The usage of the battery BT is not limited to the vehicle, and the battery BT may be used for other purposes such as an uninterruptible power supply system and an energy storage apparatus of a solar power generating system.

(2) The above embodiment shows an example in which the first current sensor 47 and the second current sensor 48 are selectively used according to the state of the vehicle V. The condition for selecting between use of the first current sensor 47 and use of the second current sensor 48 is not limited to a condition regarding the state of the vehicle V. For example, when the current value is equal to or smaller than a threshold value, the second current sensor 48 having high resolution is used. If the current value is larger than the threshold value, the first current sensor 47 having low resolution is used. Thus, use of the first current sensor 47 or the second current sensor 48 may be selected according to the current value. In short, any configuration may be adopted, as long as the current I of the assembled battery 40 is measured by selectively using the first current sensor 47 and the second current sensor 48 according to predetermined selection conditions (conditions regarding the state of the vehicle or current value conditions).

(3) In the above embodiment, the failure diagnosis of the current breaker 45 is performed while the vehicle V is parked. The failure diagnosis may be performed any time when the battery BT is being charged or discharged. Additionally, a configuration may be adopted in which the failure diagnosis is performed only on the open failures or the closed failures.

(4) In the above embodiment, the failure diagnosis of the current breaker 45 is performed on the basis of the measured value Ia of the first current sensor 47 and the measured value Ib of the second current sensor 48 when the current breaker 45 is switched to open or close. Specifically it is determined that the close failure has occurred when the measured value Ia and the measured value Ib match after a command to open is given to the current breaker 45. It is determined that the open failure has occurred when the measured value Ia and measured value Ib do not match after a command to close is given to the current breaker 45. In addition to this, a configuration may be adopted in which the failure diagnosis of the current breaker 45 is performed based only on the measured value Ib of the second current sensor 48. Specifically it may be determined that the close failure has occurred when the measured value Ib is zero (no current flows to second current sensor 48) after a command to open is given to the current breaker 45. It may be determined that the open failure has occurred when the measured value Ib is not zero (some current flows to second current sensor 48) after a command to close is given to the current breaker 45.

(5) While the switch 49 is provided in series with the second current sensor 48 in the above embodiment, the switch 49 may be omitted.

(6) The above embodiment shows an example in which the determination as to whether or not the vehicle V is parked is made on the basis of communication with the vehicle ECU 120. The determination regarding the parked state may be made by a method other than communication with the vehicle ECU 120. For example, an infrared sensor and an acceleration sensor may be used, for example, to detect the presence or absence of a passenger in a vehicle 1 and whether or not the vehicle is moving. Then, it may be determined that the vehicle 1 is parked when the unattended and stationary state continues for a predetermined time.

### DESCRIPTION OF REFERENCE SIGNS

2: Secondary battery (energy storage device)
40: Assembled battery
45: Current breaker
47: First current sensor
48: Second current sensor
50: Management device
51: Processing unit
BT: Battery (energy storage apparatus)
V: Vehicle

1. A current measuring device of an energy storage device comprising:
a current breaker that is provided on a current path of the energy storage device;
a first current sensor that is on the current path and measures a current of the energy storage device;
a second current sensor that is connected in parallel with the current breaker; and
a processing unit, wherein
the second current sensor comprises a sensor having a smaller resolution than the first current sensor, and
the processing unit performs
measurement processing of measuring the current of the energy storage device by selectively using the first current sensor and the second current sensor according to a predetermined selection condition, and
failure diagnosis processing of diagnosing whether or not there is a failure in the current breaker on the basis of a measured value of the second current sensor when the current breaker is switched to open or close.

2. The current measuring device according to claim 1, wherein
the energy storage device is used to start an engine for driving a vehicle.

3. The current measuring device according to claim 2, wherein
the processing unit opens the current breaker and measures a current of the energy storage device using the second current sensor while the vehicle is parked.

4. The current measuring device according to claim 3, wherein
the processing unit closes the current breaker and measures a current of the energy storage device using the first current sensor when the engine is started.

5. The current measuring device according to claim 1, wherein
in the failure diagnosis processing, the processing unit diagnoses whether or not there is a failure in the current breaker on the basis of whether or not a measured value of the first current sensor and a measured value of the second current sensor match.

6. An energy storage apparatus comprising:
an energy storage device;
the current measuring device according to claim 1; and
a housing that houses the energy storage device and the current measuring device.

7. A current measurement method for measuring a current of an energy storage device using a first current sensor that is arranged on a current path of the energy storage device, and a second current sensor that is connected in parallel with a current breaker arranged on the current path of the energy storage device and has a smaller resolution than the first current sensor, the method comprising the steps of
performing failure diagnosis processing of diagnosing whether or not there is a failure in the current breaker on the basis of a measured value of the second current sensor when the current breaker is switched to open or close, and
when it is determined that there is no failure in the failure diagnosis processing, performing measurement processing of measuring the current of the energy storage device by selectively using the first current sensor and the second current sensor according to a predetermined selection condition.
